(19) United States
(12) Patent Application Publication
(10) Pub. No.: US 2022/0121193 A1
(43) Pub. Date: Apr. 21, 2022

(54) TEST PULSE WIDTH CALCULATION DEVICE, CONTROL DEVICE, TEST PULSE WIDTH CALCULATION METHOD, AND PROGRAM

(71) Applicant: Mitsubishi Electric Corporation, Tokyo (JP)

(72) Inventor: Masahiro UCHIKOSHI, Tokyo (JP)

(73) Assignee: Mitsubishi Electric Corporation, Tokyo (JP)

(21) Appl. No.: 17/605,574

(22) PCT Filed: Jul. 11, 2019
(86) PCT No.: PCT/JP2019/027523

§ 371 Date: Oct. 22, 2021

(51) Int. Cl. G05B 23/02; G05B 19/05

(52) U.S. Cl. CPC G05B 23/0256; G05B 2219/14007; G05B 19/058

(57) ABSTRACT

An input/output unit is a test pulse width calculation device for calculating a time width of a test pulse for use in a failure diagnosis test of a PLC. The input/output unit includes a memory that stores a threshold for detection of noise superposed on a signal to be input to an input circuit of the PLC, and a processor. The processor includes a voltage value acquirer and a test pulse width calculator. The voltage value acquirer acquires a measurement value of voltage in an input path of the signal to be input to the input circuit. The test pulse width calculator calculates, based on the measurement value of voltage and the threshold, a reference noise width that is a reference for calculating a test pulse width, and calculates the test pulse width that is larger than the calculated reference noise width.

### TECHNICAL FIELD

The present disclosure relates to a test pulse width calculation device, a control device, a test pulse width calculation method, and program.

### BACKGROUND ART

A safety device is required to have high reliability for the purpose of preventing occurrence of accidents. A technique of ensuring high reliability by performing failure diagnosis tests while the safety device operates has been developed. For example, Patent Literature 1 discloses a safety input device that generates a test pulse, combines the generated test pulse and an input signal that is input from an external sensor, and evaluates the combined output signal.

### CITATION LIST

### Patent Literature

Patent Literature 1: Unexamined Japanese Patent Application Publication No. 2011-145988

### SUMMARY OF INVENTION

### Technical Problem

In the failure diagnosis test of the safety device, reduced accuracy of diagnosis due to noise may be a problem. As a technique to address such a problem, Patent Literature 1 discloses removing a high-frequency noise pulse by applying a low-pass filter to a noise pulse superimposed on an input signal. However, if a noise component is added to a test pulse, the technique described in Patent Literature 1 may have a problem that, for example, accuracy of testing decreases due to collapse of an off-width portion of the test pulse, preventing correct diagnosis.

In view of the above circumstances, an objective of the present disclosure is to provide a test pulse width calculation device, a control device, a test pulse width calculation method, and a program capable of securely avoiding an effect of noise and of calculating a test pulse width for correct diagnosis.

### Solution to Problem

To achieve the above objective, the test pulse width calculation device according to the present disclosure is a test pulse width calculation device for calculating a time width of a test pulse for use in a failure diagnosis test of a control device. The test pulse width calculation device includes a memory to store a threshold for detection of noise superposed on a signal to be input to an input circuit of the control device, and a processor. The processor includes a measurement value acquirer and a test pulse width calculator. The measurement value acquirer acquires an electrical measurement value in an input path of the signal to be input to the input circuit of the control device. The test pulse width calculator calculates, based on comparison between the electrical measurement value and the threshold, a reference noise width that is a reference for calculating a test pulse width, and calculates the test pulse width that is larger than the calculated reference noise width.

### Advantageous Effects of Invention

According to the present disclosure, calculating, based on the comparison between the electrical measurement value and the threshold, the reference noise width that is a reference for calculating the test pulse width, and calculating the test pulse width that is larger than the calculated reference noise width can achieve secure avoidance of an effect of noise and calculation of the test pulse width for correct diagnosis.

### BRIEF DESCRIPTION OF DRAWINGS

FIG. 1 is a hardware configuration diagram of a PLC according to an embodiment of the present disclosure;

FIG. 2 is a functional block diagram of a processor according to the embodiment of the present disclosure;

FIG. 3 is a flowchart of a test pulse width calculation process according to the embodiment of the present disclosure;

FIG. 4 is a diagram representing an example of a voltage measurement value according to the embodiment of the present disclosure;

FIG. 5 is a diagram representing an example of a waveform representing the voltage measurement value according to the embodiment of the present disclosure;

FIG. 6 is a diagram representing a relationship between noise and a test pulse according to the embodiment of the present disclosure;

FIG. 7 is a hardware configuration diagram of a PLC according to a modified example of the embodiment of the present disclosure; and

FIG. 8 is a hardware configuration diagram of a PLC according to another modified example of the embodiment of the present disclosure.

### DESCRIPTION OF EMBODIMENTS

### Embodiments

Embodiments in which a test pulse width calculation device of the present disclosure is applied to a programmable logic controller (PLC) are described hereinafter with reference to the drawings.

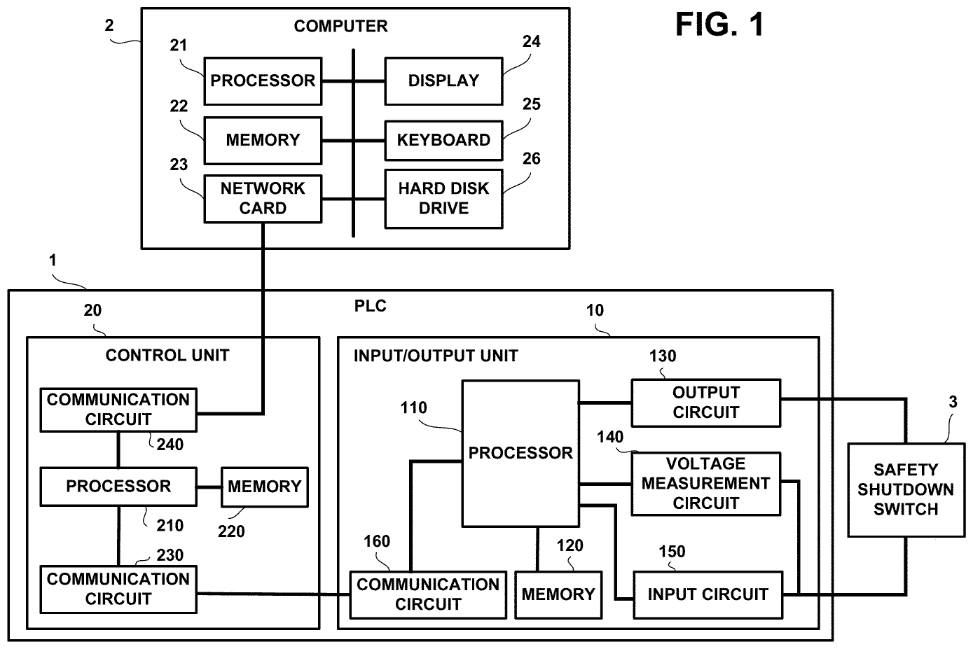

A PLC 1 according to the present embodiment is a control device that controls a safety device for preventing occurrence of an accident in a factory. Specifically, the PLC 1 is connected to each of a computer 2 and a safety shutdown switch 3, as illustrated in FIG. 1.

The safety shutdown switch 3 is, for example, turned on with a button pressed by a hand of a user during use. Then, when the hand of the user is released from the button for some reason, the shutdown button is turned off. The PLC 1 has a function of performing control to shut down various types of devices (not illustrated) upon turning off of the safety shutdown switch 3. The PLC 1 also has a function of executing, while operating, a failure diagnosis test to ensure the function for emergency shutdown of these various types of devices.

Specifically, the PLC 1 includes an input/output unit 10 for passing a signal between the PLC 1 and the safety shutdown switch 3, and a control unit 20 that executes processing for control of the various types of devices.

The input/output unit 10 includes a processor 110 that executes various types of processing, a memory 120 that stores various types of data, an output circuit 130 that outputs a signal to the safety shutdown switch 3, a voltage measurement circuit 140 that measures a voltage, an input circuit 150 that inputs a signal from the safety shutdown switch 3, and a communication circuit 160 that controls communication with the control unit 20.

The processor 110 is a calculating unit that executes the various types of processing. The processor 110 is communicatively connected to the memory 120, the output circuit 130, the voltage measurement circuit 140, the input circuit 150, and the communication circuit 160. The details of the various types of processing are described later.

The memory 120 is a main storage that stores the various types of data. The memory 120 functions as a work area of the processor 110 and stores various types of data. The memory 120 stores setting values referred to by the processor 110 in a process described later. Specifically, the setting values include a voltage measurement interval Im, the number of voltage measurements Nm, a noise detection threshold Th, and a minimum diagnosis time width Wm. The meaning of these setting values is described later.

The output circuit 130 is an electronic circuit that receives a digital signal from the processor 110 and sends an analog signal to the safety shutdown switch 3 through D/A conversion. The output circuit 130 outputs a test pulse for the failure diagnosis test.

The voltage measurement circuit 140 is an electronic circuit that measures the voltage in an input path of a signal to be input to the input circuit 150. The voltage measurement circuit 140 sends a signal indicating a measurement value of the voltage to the processor 110. The voltage measurement circuit 140 is an example of an electrical measurement circuit described in the claims. The measurement value of the voltage is an example of an electrical measurement value described in the claims.

The input circuit 150 is an electronic circuit that receives the signal input by the safety shutdown switch 3 and sends a digital signal to the processor 110 through A/D conversion.

The communication circuit 160 is an electronic circuit that controls the communication with the control unit 20.

The control unit 20 controls various types of devices (not illustrated). The control unit 20 includes a processor 210 that executes various types of processing, a memory 220 that stores various types of data, a communication circuit 230 that controls communication with the input/output unit 10, and a communication circuit 240 that controls communication with the computer 2.

Upon receiving an operation by a user, the computer 2 creates a ladder program that specifies processing details for the PLC 1 to control the various types of devices, or acquires various types of information from the PLC 1 and displays the information. The computer 2 is communicatively connected to the control unit 20 of the PLC 1 and sends the generated ladder program to the control unit 20.

The computer 2 includes a processor 21 that executes various types of processing, a memory 22 that stores various types of information, a network card 23 for sending and receiving information, a display 24 that displays information, a keyboard 25 that accepts an operation, and a hard disk drive 26 that stores various types of information.

The processor 21 retrieves into the memory 22 an engineering tool stored in the hard disk drive 26 and executes the engineering tool, thereby executing processing, such as generation of the ladder program, display of various types of information, and the like.

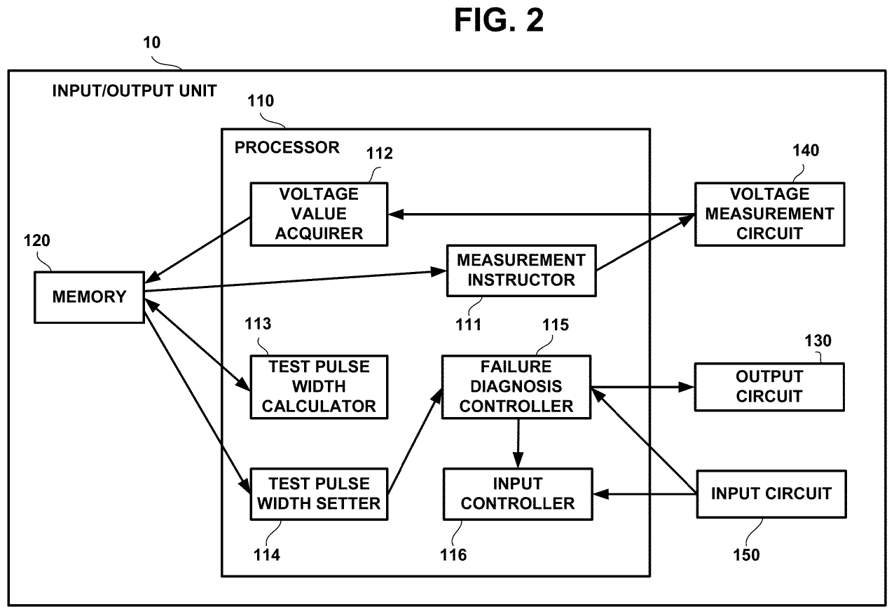

Next, processing executed by the processor 110 of the input/output unit 10 is described with reference to FIG. 2.

The processor 110 includes a measurement instructor 111 that issues an instruction for measurement of voltage, a voltage value acquirer 112 that acquires a voltage value, a test pulse width calculator 113 that calculates a test pulse width, a test pulse width setter 114 that sets the test pulse width, a failure diagnosis controller 115 that executes a failure diagnosis test, and an input controller 116 that performs control by an input signal.

The measurement instructor 111 instructs the voltage measurement circuit 140 to measure voltage. Specifically, the measurement instructor 111 issues the instruction for the measurement of voltage based on the voltage measurement interval Im and the number of voltage measurements Nm recorded in the memory 120. Here, the voltage measurement interval Im indicates an interval in time for measurement of voltage. The number of voltage measurements Nm indicates the number of times of the measurement of voltage.

The voltage value acquirer 112 acquires the voltage value from the voltage measurement circuit 140 and records the acquired voltage value in memory 120. The voltage value acquirer 112 is an example of a measurement value acquirer described in the claims.

The test pulse width calculator 113 calculates the test pulse width based on the voltage value recorded in the memory 120. The test pulse width is a time width of a test pulse for the PLC 1 to use in the failure diagnosis test. Specifically, the test pulse width calculator 113 determines, based on the noise detection threshold Th stored in the memory 120, whether or not each voltage value is noise. Then the test pulse width calculator 113 calculates the test pulse width based on the result of the determination and the minimum diagnosis time width Wm stored in the memory 120. These specific calculation methods are described later. The test pulse width calculator 113 stores in the memory 120 information indicating the calculated test pulse width.

The test pulse width setter 114 sets, as the test pulse width in failure diagnosis, the test pulse width calculated by the test pulse width calculator 113. Specifically, the test pulse width setter 114 retrieves from the memory 120 the information indicating the test pulse width, and indicates, to the failure diagnosis controller 115, the time width of the test pulse for use in the failure diagnosis test.

The failure diagnosis controller 115 executes the failure diagnosis test. Specifically, upon starting the failure diagnosis test, the failure diagnosis controller 115 sends, to the output circuit 130, an instruction to generate a test pulse having the test pulse width indicated by the test pulse width setter 114. The generated test pulse is assumed to be an OFF signal, and the failure diagnosis controller 115 diagnoses that an abnormality occurs if the OFF signal cannot be detected. The failure diagnosis controller 115 notifies the input controller 116 of start and end of the failure diagnosis test. The failure diagnosis controller 115 diagnoses, based on the signal received from the input circuit 150, whether or not a failure occurs.

The input controller 116 performs control by the input signal input by the input circuit 150. Specifically, the input controller 116 sends a signal via the communication circuit 160 to the control unit 20 based on the input signal input by the input circuit 150. The control unit 20 controls the various types of devices based on the received signal. For example, upon the user releasing the button of the safety shutdown switch 3, the OFF signal is sent via the input circuit 150 to the input controller 116. Then the input controller 116 sends the signal to the control unit 20, and thereby the control unit 20 performs control to shut down the various types of devices. Upon receiving notification of the start of the failure diagnosis test from the failure diagnosis controller 115, the input controller 116 ignores the signal received from the input circuit 150 until receiving notification of the end of the failure diagnosis test.

Next, operation of the PLC 1 is described with reference to the drawings.

Before starting operation of the PLC 1, a user stores beforehand as setting values the voltage measurement interval Im and the number of voltage measurements Nm in the memory 120. Specifically, the user operates the computer 2 illustrated in FIG. 1 to start up the engineering tool and enter each setting value using the keyboard 25. The computer 2 sends the entered setting values via the network card 23 to the PLC 1. The PLC 1 stores the received setting values in the memory 120.

Preferably, the number of voltage measurements Nm is set in consideration of capacity of the memory 120. Since the capacity of the memory 120 for use in a single voltage measurement is predictable from a format of information to be written into the memory 120, the number of times may be set that enables measurement of the voltage Nm times. Also, preferably, the voltage measurement interval Im is set in consideration of a line cycle of a factory, a facility, or the like where the PLC 1 operates, and the set number of voltage measurements Nm. This is because considering the line cycle is particularly effective to increase accuracy of the failure diagnosis test in which removal of effects of noise caused by a periodic operation is performed continuously. Thus the user has to set the voltage measurement interval Im to be large enough to acquire data having a duration necessary for checking the effect of noise occurring in the periodic operation. However, the larger voltage measurement interval Im may decrease precision in the checking of the effect of noise. Thus the voltage measurement interval Im is to be set in consideration of the tradeoff.

The noise detection threshold Th is determined beforehand and stored in the memory 120 based on a design value for voltage detection of the input circuit 150. The noise detection threshold Th is a threshold for detection of noise.

The minimum diagnosis time width Wm is determined beforehand and stored in the memory 120 based on a response speed of the input circuit 150 and a processing cycle of the processor 110. The minimum diagnosis time width Wm indicates a minimum time width necessary for correct diagnosis in the failure diagnosis test.

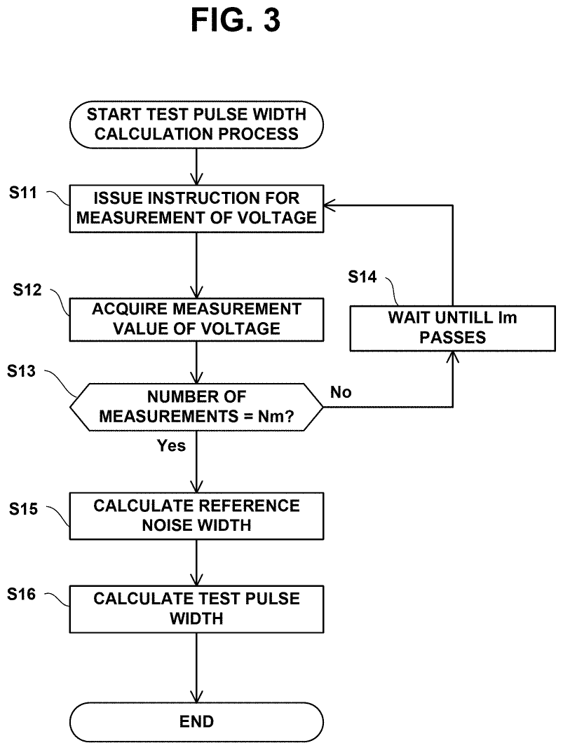

When the user issues an instruction for starting of the test pulse width calculation process by operating the computer 2 after inputting each setting value, the input/output unit 10 of the PLC 1 receives via the control unit 20 an instruction to calculate the test pulse width. Then the processor 110 starts the test pulse width calculation process illustrated in FIG. 3. In the test pulse width calculation process, the output circuit 130 does not output a signal. In other words, the output circuit 130 outputs an OFF signal. Thus, the input controller 116 is set beforehand to ignore the signal even upon reception of the OFF signal. However, preferably, the test pulse width calculation process is started while causing noise in a situation similar, as much as possible, to the actual operating situation.

The measurement instructor 111 of the processor 110 instructs the voltage measurement circuit 140 to measure voltage (step S11). Upon receiving the instruction for the measurement of voltage, the voltage measurement circuit 140 measures voltage of communication line between a terminal of an input line from the safety shutdown switch 3 and the input circuit 150. The voltage measurement circuit 140 sends to the processor 110 a digital signal indicating the measurement value.

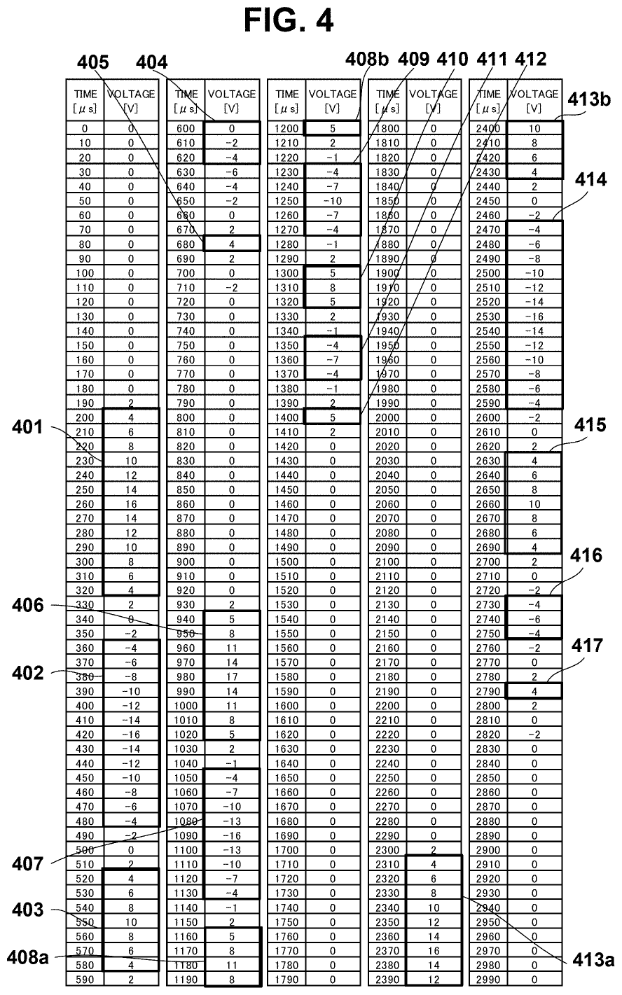

The voltage value acquirer 112 of the processor 110 receives the signal indicating the measurement value of voltage from the voltage measurement circuit 140 and records the measurement value of voltage in the memory 120 (step S12). This step S12 is an example of a measurement value acquisition step described in the claims. The measurement instructor 111 determines whether the number of measurements reaches the number of voltage measurements Nm, that is, whether or not the number of measurements equals Nm (step S13). Upon determining that the number of measurements does not equal Nm (No in step S13), the measurement instructor 111 waits until the voltage measurement interval Im passes (step S14) and then executes processing of step S11 again. FIG. 4 illustrates an example of voltage values stored in the memory 120 by these process steps, assuming that Im=10 (μs) and Nm=300 (times), for example. Although FIG. 4 includes elapsed time from the start of the measurement, storage of the voltage value alone in the memory 120 is enough because the elapsed time can be found based on the voltage measurement interval Im.

With reference again to FIG. 3, upon the measurement instructor 111 determining that the number of measurements equals Nm (Yes in step S13), the test pulse width calculator 113 calculates a reference noise width (step S15). Specifically, the test pulse width calculator 113 compares each voltage value with the noise detection threshold Th, which are recorded in the memory 120, and classifies as noise data a voltage value having an absolute value that is not less than the noise detection threshold Th. Here, the time widths for noise data consecutive overtime are taken as a provisional noise width and referenced as a provisional noise width 1, a provisional noise width 2, a provisional noise width 3, . . . , and a provisional noise width N in a chronological order. Also, the intervals between these time widths are taken as a provisional noise interval and referenced as a provisional noise interval 1, a provisional noise interval 2, a provisional noise interval 3, . . . , and a provisional noise interval M Here, M=N−1.

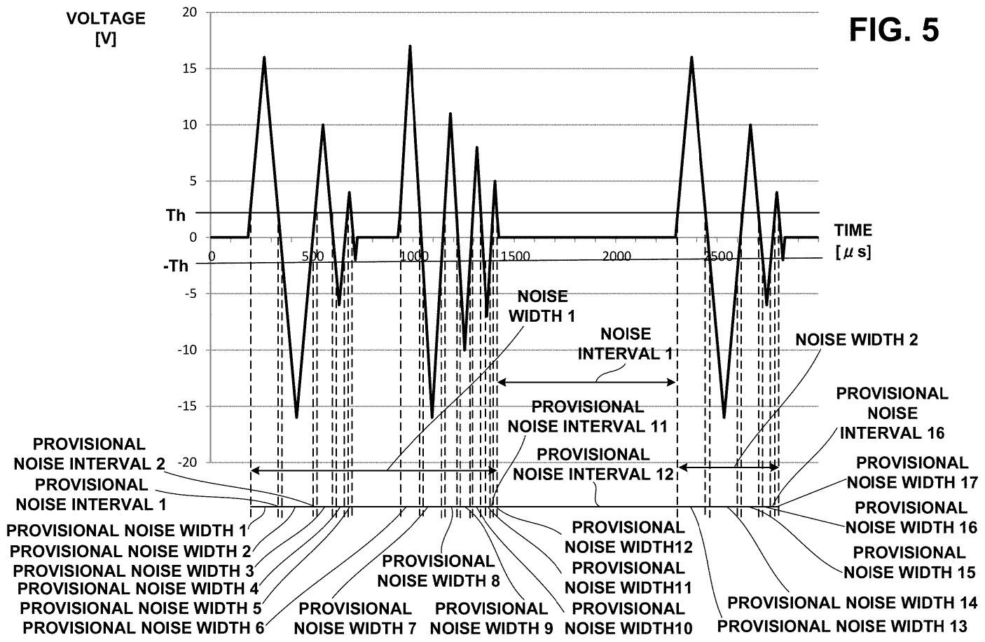

For example, when the noise detection threshold Th equals 3 (V) and the voltage value illustrated in FIG. 4 is recorded in the memory 120, the test pulse width calculator 113 classifies as the noise data the voltage values enclosed by each of rectangles 401 to 417 because the absolute values of the voltage values in each rectangle are not less than Th. The time width of the voltage values enclosed by the rectangle 401 is taken as the provisional noise width 1, and similarly, the time widths of the voltage values enclosed by the rectangles 402, 403, 404, 405, 406, 407, 408a and 408b, 409, 410, 411, 412, 413a and 413b, 414, 415, 416, and 417 are taken as the provisional noise widths 2, 3, . . . , and 17, respectively, as illustrated in FIG. 5. Also, the intervals between these sets of noise data are taken as the provisional noise interval and referenced as the provisional noise interval 1, the provisional noise interval 2, the provisional noise interval 3, . . . , and the provisional noise interval 16.

Next, the test pulse width calculator 113 determines whether each provisional noise interval is twice the minimum diagnosis time width Wm or more. Then the test pulse width calculator 113 groups as a series of noise data the noise data that correspond to the provisional noise widths on both sides of the provisional noise interval for which the interval is determined as being shorter than twice the width Wm. Conversely, the test pulse width calculator 113 classifies as the noise data of another group the noise data that is on the both sides of the interval for which the interval is determined as being not less than twice the width Wm. As for the noise data newly grouped in this way, the time width including the original provisional noise interval is taken as the noise width and referenced as a noise width 1, a noise width 2, a noise width 3, . . . , and a noise width L in a chronological order. In addition, the intervals between the noise widths are taken as a noise interval and referenced as a noise interval 1, a noise interval 2, . . . , and a noise interval K. Here, K=L−1. The noise width is a provisional noise width to which a modification is added, and is an example of a modified noise width described in the claims.

For example, in the example of FIG. 5, when determination is made that all of the noise intervals of the provisional noise intervals 1 to 11 are less than twice the width Wm and the provisional noise interval 12 is not less than twice the width Wm, data from the provisional noise width 1 to the provisional noise width 12 serve as a series of noise data. Then the noise width 1, which is a time width obtained by adding a total of the provisional noise intervals from the provisional noise interval 1 to the provisional noise interval 11 to a total of the provisional noise widths from the provisional noise width 1 to the provisional noise width 12, satisfies the following equation.

Noise width 1=provisional noise width 1+provisional noise interval 1+provisional noise width 2+provisional noise interval 2+. . . +provisional noise interval 11+provisional noise width 12.

Similarly, when all of the noise intervals from the provisional noise interval 13 to the provisional noise interval 16 are less than twice the width Wm, the noise width 2 satisfies the following equation.

Noise width 2=provisional noise width 13+provisional noise interval 13+provisional noise width 14+provisional noise interval 14+. . . +provisional noise interval 16+provisional noise width 17

Next, the test pulse width calculator 113 compares the calculated noise widths with each other and takes the largest noise width as the reference noise width. In the example of FIG. 5, when the calculated noise widths are the noise width 1 and the noise width 2, the test pulse width calculator 113 compares these noise widths and takes, as the reference noise width, the noise width 1 having a larger noise width.

With reference again to FIG. 3, next, the test pulse width calculator 113 calculates the test pulse width based on the calculated reference noise width (step S16). Specifically, the test pulse width calculator 113 calculates the test pulse width Pw based on the reference noise width Nw by the following equation.

Pw=Nw+2×Wm

The test pulse width calculator 113 records the calculated test pulse width Pw into the memory 120. Step S15 and step S16 are an example of a test pulse width calculation step described in the claims.

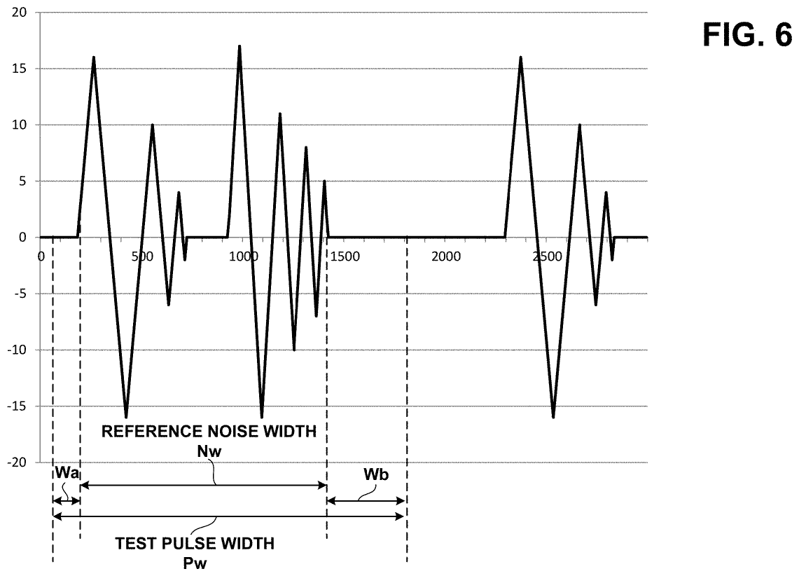

In this way, the processor 110 executes the test pulse width calculation process to calculate the test pulse width. If the same noise as the noise at the time of execution of the test pulse width calculation process occurs in the failure diagnosis test executed with the calculated test pulse width, a noise-effect-free OFF width having at least Wm is ensured regardless of a phase relationship between the test pulse and the noise. As illustrated in FIG. 6, even in a case of the phase relationship in which the test pulse width Pw contains the whole reference noise width Nw, noise-effect-free time widths Wa and Wb satisfy the equation: Wa+Wb=Pw−Nw=2×Wm. This results in either of Wa or Wb being not less than Wm. Thus the calculated test pulse width Pw has a proper length that is not too large while avoiding the effect of noise. The effect of noise can be avoided since a portion that is not affected by a noise component is ensured if the test pulse width Pw is made larger. However, if the test pulse width Pw is too large, conducting of the failure diagnosis test might affect operation of the safety device, which is unacceptable in the actual operation. Thus setting the test pulse width Pw to a proper length that is not too large is useful.

The PLC 1 conducts the failure diagnosis test periodically during the actual operation, for example, every one hour. The test pulse width setter 114 retrieves the test pulse width Pw recorded in the memory 120 and indicates, to the failure diagnosis controller 115, the test pulse width in the failure diagnosis test.

The failure diagnosis controller 115 sends to the output circuit 130 an instruction to generate the test pulse of the test pulse width Pw, and notifies the input controller 116 of the start of the failure diagnosis test. Upon receiving notification of the start the failure diagnosis test from the failure diagnosis controller 115, the input controller 116 enters a state of ignoring a signal received from the input circuit 150.

The output circuit 130 generates the test pulse of the test pulse width Pw and sends a signal to the safety shutdown switch 3. The button of the safety shutdown switch 3 is pressed by the user. Thus the safety shutdown switch 3 is turned on during use and sends the ON signal output by the output circuit 130 as is to the input circuit 150. Then upon sending of the test pulse of the OFF signal from the output circuit 130, the test pulse of the OFF signal is sent to as is to the input circuit 150.

Upon sending of the OFF signal, the input circuit 150 sends a digital signal indicating OFF through A/D conversion to the processor 110. The failure diagnosis controller 115 diagnoses, based on the signal received from the input circuit 150, whether or not a failure occurs. Then, upon end of the failure diagnosis, the failure diagnosis controller 115 notifies the input controller 116 of the end of the failure diagnosis test. Upon receiving the notification of the end of the failure diagnosis test from the failure diagnosis controller 115, the input controller 116 cancels the state of ignoring the signal received from the input circuit 150 and restarts control by the signal received from the input circuit 150.

By calculation a width of actually occurring noise, the PLC 1 according to the above-described embodiment can calculate, even if noise having the same noise width occurs in the failure diagnosis test, the test pulse width large enough to avoid the effect of the noise.

In the PLC 1 according to the above-described embodiment, a value greater than at least 0 is set to the minimum diagnosis time width Wm. Thus the test pulse width Pw calculated by Pw=Nw+2×Wm is greater than the reference noise width Nw. Also, the reference noise width Nw is made greater than any of the provisional noise widths calculated by the test pulse width calculator 113, and thus the test pulse width is greater than any of the provisional noise widths.

When the provisional noise interval is less than twice the minimum diagnosis time width Wm, the noise occurrences are determined as continuous noise. Even when a plurality of noises occurs continuously in a short interval, the noises can be thereby handled as a series of noises, and thus the noise-effect-free test pulse width with the ensured width not less than the minimum diagnosis time width Wm can be calculated.

### Modified Example

The present disclosure is not limited to the above-described embodiment, and other various types of modifications can be made.

In the above-described embodiment, the input/output unit 10 of the PLC 1 is an example of a test pulse width calculation device described in the claims. In the hardware configuration illustrated in FIG. 1, the control unit 20 may be used as the test pulse width calculation device instead of the input/output unit 10. In such a case, the processor 210 of the control unit 20 serves each function illustrated in FIG. 2, and records each type of the setting values in the memory 220 of the control unit 20 instead of the memory 120 of the input/output unit 10. Similarly, the computer 2 may be used as the test pulse width calculation device. In such a case, the processor 21 of the computer 2 servers each function illustrated in FIG. 2, and records each type of the setting values in the memory 22 of the computer 2 instead of the memory 120 of the input/output unit 10.

The above-described embodiment exemplifies, as the safety device, the safety shutdown switch 3 that is a device that receives a signal from the PLC 1 and outputs the signal as is. However, the PLC 1 may be applied to another type of safety device. For example, the PLC 1 may be applied to a signal output device that outputs a signal or a signal input device that inputs a signal.

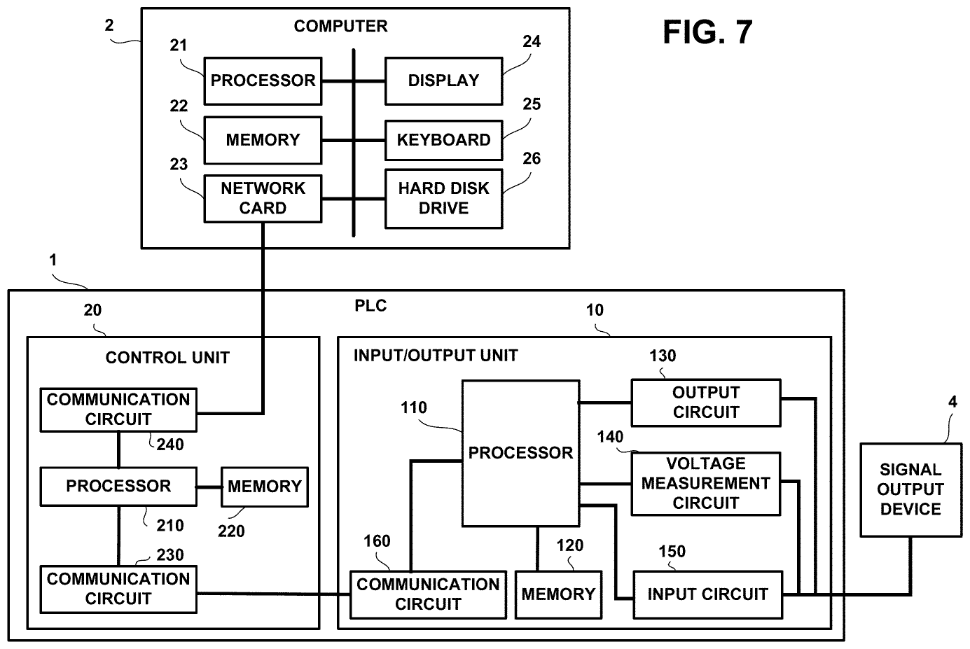

An example in which the PLC 1 is applied to a signal output device 4 is illustrated in FIG. 7. In this case, the signal output by the output circuit 130 and the signal output by the signal output device 4 both reach the input circuit 150. A configuration may be used in which, when the failure diagnosis test is not executed, the signal output by the signal output device 4 reaches the input circuit 150, and when the failure diagnosis test is operated, the signal output by the signal output device 4 is canceled and the signal output by the output circuit 130 reaches the input circuit 150.

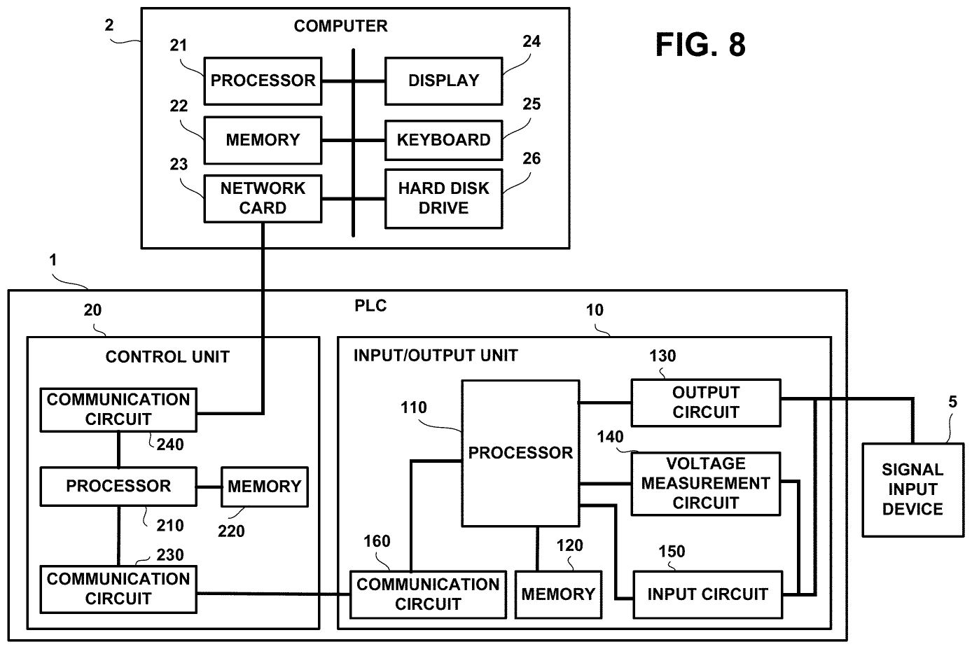

An example of applying the PLC 1 to a signal input device 5 is illustrated in FIG. 8. In this case, the signal output by the output circuit 130 is sent to the signal input device 5, and a readback signal of the output signal is sent to the input circuit 150. The output circuit 130 according to the present modified example sends a signal for control to the signal input device 5 during actual operation. Then, when the failure diagnosis test is performed, the output circuit 130 combines the signal for control and the test pulse and outputs the combined signal. Since the combined signal causes reflection of the OFF signal of the test pulse as the OFF signal as is, the output circuit 130 applies an AND operation to the signal for control and the test pulse and combines the signal and the test pulse.

In the PLC 1 according to the above-described embodiment and modified example, the configurations illustrated in FIGS. 1, 7, and 8 can be concurrently adopted. For example, a plurality of output circuits 130 and a plurality of input circuits 150 may be included. In such a case, the voltage measurement circuit 140 may perform measurement for each of input paths of signals that are input to the plurality of input circuits 150, or a plurality of voltage measurement circuits 140 may perform measurement for the input paths of signals that are input to the corresponding input circuits 150.

The above-described embodiment provides an example in which the test pulse is the OFF signal. Since the OFF signal is greatly susceptible to noise, proper setting of the test pulse width is quite necessary. However, the test pulse may also be an ON signal. When the test pulse is the ON signal, the output circuit 130 sends the ON signal during execution of the test pulse width calculation process. Then, in the calculation of the noise width, the noise detection threshold Th is not compared with the absolute value, that is, a value determined while 0 (V) is taken as a reference, but may be compared with an amount increased or decreased from a voltage value that is a reference of the ON signal, for example, 24 (V). In this case, since the output circuit 130 can execute the test pulse width calculation process while outputting the ON signal, the test pulse width can be calculated even during the actual operation when the safety shutdown switch 3 is in operation.

The above-described embodiment provides an example in which the voltage measurement circuit 140 measures the voltage in the input path of the signal to be input to the input circuit 150. However, electrical measurement other than voltage measurement may be performed. For example, the measurement value may be current, electrical power, and the like. In this case, a value corresponding to the type of the measurement value is set to the noise detection threshold Th.

The method for calculating the reference noise width and the test pulse width in the above-described embodiment is an example of the method for calculating the test pulse width having the proper length. But these calculation methods are not limited to the above-described embodiment. For example, the maximum value of the provisional noise width may be simply taken as the reference noise width without any modification to the provisional noise width. This can achieve process simplification and cost reduction in system introduction. However, since the accuracy of the failure diagnosis test is lowered, selection is to be made in consideration of trade-off between both the cost and the accuracy of the failure diagnosis test. Alternatively, the reference noise width may be calculated using a statistic value other than the maximum value, such as an average value, a variance value, and the like of the provisional noise width or the modified noise width. Calculation of the reference noise width using the statistic value can remove an effect due to abnormal noise and achieve calculation of a more practical test pulse width. Also, calculation of the reference noise width using the maximum value of the provisional noise width or the modified noise width can achieve calculation of a highly safe test pulse width that takes into consideration the effect of abnormal noise.

The above-described embodiment provides an example in which the operation of the computer 2 by the user starts calculation of the test pulse width. As another example, in a case of a determined periodic time such as a maintenance time, the processor 110 of the PLC 1 may start the test pulse width calculation process upon timer startup. Alternatively, the test pulse width calculation process may be started by a user pressing a not-illustrated switch included in the PLC 1.

The above-described embodiment provides an example in which the test pulse width setter 114 sets the test pulse width calculated by the test pulse width calculator 113. Alternatively, the test pulse width calculated by the test pulse width calculator 113 may be displayed on the display 24 of the computer 2. Then, the user may input the test pulse width by referring to the test pulse width displayed on the display 24, and the test pulse width setter 114 may set the input test pulse width input.

The processor 21 of the computer 2, the processor 210 of the control unit 20, and the processor 110 of the input/output unit 10 according to the above-described embodiment correspond to, for example, a central processing unit (CPU), a microprocessor, a digital signal processor (DSP), and the like. The memory 22 of the computer 2, the memory 220 of the control unit 20, and the memory 120 of the input/output unit 10 includes a volatile or non-volatile memory, and correspond to, for example, a random access memory (RAM), a read only memory (ROM), a flash memory, an erasable programmable read only memory (EPROM), an electrically erasable programmable read-only memory (EEPROM), and the like.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

1 PLC

2 Computer

3 Safety shutdown switch

4 Signal output device

5 Signal input device

10 Input/output unit

20 Control unit

21 Processor

22 Memory

23 Network card

24 Display

25 Keyboard

26 Hard disk drive

110 Processor

111 Measurement instructor

112 Voltage value acquirer

113 Test pulse width calculator

114 Test pulse width setter

115 Failure diagnosis controller

116 Input controller

120 Memory

130 Output circuit

140 Voltage measurement circuit

150 Input circuit

160 Communication circuit

210 Processor

220 Memory

230, 240 Communication circuit

401, 402, 403, 404, 405, 406, 407, 408a, 408b, 409, 410, 411, 412, 413a, 413b, 414, 415, 416, 417 Rectangle

1. A test pulse width calculation device for calculating a time width of a test pulse for use in a failure diagnosis test of a control device, the test pulse width calculation device comprising:
a memory to store a threshold for detection of noise superposed on a signal to be input to an input circuit of the control device; and
a processor, wherein
the processor comprises
a measurement value acquirer to acquire an electrical measurement value in an input path of the signal to be input to the input circuit, and
a test pulse width calculator to calculate, based on comparison between the electrical measurement value and the threshold, a reference noise width that is a reference for calculating a test pulse width and calculate the test pulse width that is larger than the calculated reference noise width,
the test pulse width calculator acquires, as a provisional noise width, a time width in which an absolute value of the electrical measurement value is consecutively over time not less than the threshold, and
in a case where the provisional noise width is a plurality of provisional noise widths, when an interval between the plurality of provisional noise widths is smaller than a predetermined value, the test pulse width calculator calculates, as the reference noise width, a maximum value of a modified noise width obtained by summing the plurality of provisional noise widths and the interval between the plurality of provisional noise widths, and calculates the test pulse width that is larger than the calculated reference noise width.

2. (canceled)

3. The test pulse width calculation device according to claim 1, wherein
the memory further stores a minimum diagnosis time width indicating a minimum time width necessary for correct diagnosis, and
the predetermined value is twice the minimum diagnosis time width.

4. The test pulse width calculation device according to claim 3, wherein
the test pulse width calculator calculates the test pulse width that is a sum of the reference noise width and twice the minimum diagnosis time width.

5. A control device comprising:
a processor;
an output circuit to output a test pulse for a failure diagnosis test;
an input circuit to input the test pulse;
a memory to store a threshold for detection of noise superposed on a signal to be input to the input circuit of the control deice; and
an electrical measurement circuit to perform electrical measurement on an input path of the signal to be input to the input circuit, wherein
the processor comprises
a measurement value acquirer to acquire an electrical measurement value from the electrical measurement circuit,
a test pulse width calculator to calculate, based on comparison between the electrical measurement value and the threshold, a reference noise width that is a reference for calculating a test pulse width and calculate the test pulse width that is larger than the calculated reference noise width, and
a test pulse width setter to set the test pulse of the output circuit to the test pulse width calculated by the test pulse width calculator,
the test pulse width calculator acquires, as a provisional noise width, a time width in which an absolute value of the electrical measurement value is consecutively over time not less than the threshold, and
in a case where the provisional noise width is a plurality of provisional noise widths, when an interval between the plurality of provisional noise widths is smaller than a predetermined value, the test pulse width calculator calculates, as the reference noise width, a maximum value of a modified noise width obtained by summing the plurality of provisional noise widths and the interval between the plurality of provisional noise widths, and calculates the test pulse width that is larger than the calculated reference noise width.

6. The control device according to claim 5, wherein
the test pulse is an OFF signal, and
the electrical measurement circuit performs electrical measurement on the input path of the signal to be input to the input circuit when the output circuit sends the OFF signal.

7. The control device according to claim 5, wherein
the test pulse is an ON signal, and
the electrical measurement circuit performs electrical measurement on the input path of the signal to be input to the input circuit when the output circuit sends the ON signal.

8. The control device according to claim 5, wherein the electrical measurement circuit measures, as the electrical measurement value, voltage in the input path to the input circuit.

9. A test pulse width calculation method for calculating a time width of a test pulse for use in a failure diagnosis test of a control device, the test pulse width calculation method comprising:
acquiring an electrical measurement value in an input path of a signal to be input to an input circuit of the control device; and
calculating, based on comparison between the electrical measurement value and a threshold for detection of noise superimposed on the signal to be input to the input circuit, a reference noise width that is a reference for calculating a test pulse width, and calculating the test pulse width that is larger than the calculated reference noise width, wherein
the calculating includes acquiring, as a provisional noise width, a time width in which an absolute value of the electrical measurement value is consecutively over time not less than the threshold, and
in a case where the provisional noise width is a plurality of provisional noise widths, when an interval between the plurality of provisional noise widths is smaller than a predetermined value, the calculating includes calculating, as the reference noise width, a maximum value of a modified noise width obtained by summing the plurality of provisional noise widths and the interval between the plurality of provisional noise widths, and calculating the test pulse width that is larger than the calculated reference noise width.

10. (canceled)
